(19) United States
(12) Patent Application Publication
(10) Pub. No.: US 2025/0208228 A1
(43) Pub. Date: Jun. 26, 2025

(54) BATTERY SYSTEM AND ELECTRIFIED VEHICLE

(71) Applicant: TOYOTA JIDOSHA KABUSHIKI KAISHA, Toyota-shi (JP)

(72) Inventors: Yuki SUGO, Seto-shi (JP); Takashi OGURA, Seto-shi (JP); Hiroshi YOSHIDA, Anjo-shi (JP)

(73) Assignee: TOYOTA JIDOSHA KABUSHIKI KAISHA, Toyota-shi (JP)

(21) Appl. No.: 18/889,423

(22) Filed: Sep. 19, 2024

(30) Foreign Application Priority Data
Dec. 20, 2023 (JP) 2023-214647

(51) Int. Cl. G01R 31/392; G01R 31/374; G01R 31/387; H01M 10/48

(52) U.S. Cl. CPC G01R 31/392; G01R 31/374; G01R 31/387; H01M 10/486

(57) ABSTRACT

The battery ECU updates the frequency data of the area having the temperature and SOC of the battery as parameters, and estimates the degree of degradation (amount of degradation) from the frequency data and the degradation coefficient that increases as the temperature increases. When the battery is replaced, the battery ECU obtains an estimated full charge capacity value of the replaced battery, and calculates a degree of degradation of the replaced battery from a difference from the full charge capacity at the time of the new battery. Then, new frequency data is created based on the degree of degradation. The new frequency data is created as frequency data of an area having a high temperature and a large SOC, and the other area is null.

### CROSS-REFERENCE TO RELATED APPLICATION

This application claims priority to Japanese Patent Application No. 2023-214647 filed on Dec. 20, 2023, incorporated herein by reference in its entirety.

### BACKGROUND

### 1. Technical Field

The present disclosure relates to battery systems and electrified vehicles.

### 2. Description of Related Art

Japanese Unexamined Patent Application Publication No. 2023-109010 (JP 2023-109010 A) discloses a technique of restoring an amount of degradation of a battery when a battery electronic control unit (ECU) for calculating a cumulative amount of damage to a battery mounted on a vehicle is replaced. JP 2023-109010 A describes that an amount of degradation of a battery can be appropriately restored without being affected by the communication time for information that is received from an electronic fuel injection (EFI) ECU.

### SUMMARY

The higher the battery temperature, the more the degradation of the battery progresses. Therefore, there are cases where the degree of degradation (amount of damage and amount of degradation) of a battery is estimated according to Arrhenius law using the frequency distribution (history) of the battery temperature. In this case, the higher the frequency of the high temperature state, the larger the degree of degradation of the battery (the more the degradation of the battery is accelerated).

The frequency distribution of the battery temperature is a history of the battery temperature during the period of use of the battery. Hereinafter, this history data is also referred to as “frequency data.” The longer the battery is used, the larger the amount of frequency data.

There are cases where the battery is replaced without replacing a control device that estimates the degree of degradation (battery ECU in JP 2023-109010 A). In this case, frequency data stored in a memory of the control device is frequency data of the battery before the replacement, the degree of degradation of a replaced battery cannot be estimated using this frequency data.

An object of the present disclosure is to make it possible to estimate the degree of degradation of a replaced battery using frequency data when a battery is replaced.

A battery system of the present disclosure includes: a battery; a temperature sensor configured to detect a battery temperature that is a temperature of the battery; and a control device configured to estimate a degree of degradation of the battery. The control device is configured to estimate the degree of degradation using frequency data of the battery temperature and a degradation coefficient, and the frequency data is stored in a memory of the control device, the degradation coefficient being set in such a way that a degradation rate increases as the battery temperature increases. The control device is configured to, when the battery is replaced, acquire an estimated full charge capacity value of a replaced battery, calculate the degree of degradation of the replaced battery based on a full charge capacity when the replaced battery is new and the estimated full charge capacity value, create new frequency data in such a way that the frequency data becomes the amount of degradation of the replaced battery, and estimate the degree of degradation using the new frequency data and the degradation coefficient.

With this configuration, the control device estimates the degree of degradation using the frequency data of the battery temperature and the degradation coefficient set in such a way that the degradation rate increases as the battery temperature increases. The frequency data is stored in the memory of the control device.

When the battery is replaced, the degree of degradation of the replaced battery cannot be estimated using the frequency data stored in the memory.

With this configuration, when the battery is replaced, the control device acquires the estimated full charge capacity value of the replaced battery. The control device then calculates the degree of degradation of the replaced battery based on a full charge capacity when the replaced battery is new and the estimated full charge capacity value. The control device creates new frequency data in such a way that the frequency data becomes the degree of degradation of the replaced battery. The control device then estimates the degree of degradation using the new frequency data and the degradation coefficient. Since the new frequency data is created as data corresponding to the degree of degradation of the replaced battery, the degree of degradation of the replaced battery can be estimated using the new frequency data and the degradation coefficient.

Preferably, the control device may be configured to create the new frequency data in such a way that the frequency data in a region where the degradation rate is equal to or higher than a predetermined value becomes the degree of degradation of the replaced battery.

With this configuration, the new frequency data is created in such a way that the frequency data in the region where the degradation rate is equal to or higher than the predetermined value becomes the degree of degradation of the replaced battery. Since the degradation rate is set in such a way that the degradation rate increases as the battery temperature increases, the region for which the new frequency data is created is, for example, a high temperature region that is a predetermined temperature or higher. Batteries are typically used less frequently at temperatures lower than and higher than a normal operating temperature range. Since the battery is less frequently used in the high temperature region for which the new frequency data is created, the memory area of the control device is less likely to overflow after the replacement. The degradation coefficient is set in such a way that the degradation rate increases as the battery temperature increases. When the frequency data is created so as to become the degree of degradation of the replaced battery, the amount of data is smaller when the frequency data is created in the high temperature region of the battery temperature (region where the degradation rate is equal to or higher than the predetermined value) than when the frequency data is created in a low temperature region of the battery temperature (region where the degradation rate is low). The memory area of the control device is therefore less likely to overflow after the battery is replaced.

Preferably, the frequency data may be a history of the battery temperature and a state of charge (SOC) of the battery.

The degradation rate of a battery varies with its SOC, and degradation tends to be accelerated in, for example, a high SOC region. With this configuration, since the frequency data is a history of the battery temperature and the SOC of the battery, and the degree of degradation is estimated in view of the SOC, the estimation accuracy of the degree of degradation can be improved.

Preferably, the control device may be configured to store the frequency data in a nonvolatile memory of the control device when the battery system is shut down.

With this configuration, the frequency data is stored in the nonvolatile memory of the control device when the system is shut down. Therefore, the frequency data is less likely to be erased even in the event of a power outage of the control device.

An electrified vehicle according to the present disclosure is an electrified vehicle including the above battery system.

With this configuration, even after the battery is replaced, the degree of degradation of the replaced battery mounted on the vehicle can be estimated.

According to the present disclosure, when the battery is replaced, the degree of degradation of the replaced battery can be estimated using the frequency data.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is an entire configuration diagram of an electrified vehicle in which a battery system according to the present embodiment is mounted;

FIG. 2 is a flow chart illustrating an exemplary battery degradation estimation process performed in the battery ECU;

FIG. 3A is a diagram describing a degradation coefficient and frequency data according to the present embodiment;

FIG. 3B is a diagram describing a degradation coefficient and frequency data according to the present embodiment;

FIG. 3C is a diagram for explaining a degradation coefficient and frequency data according to the present embodiment;

FIG. 4 is a flow chart illustrating an exemplary battery replacement process performed in the battery ECU; and

FIG. 5 is a diagram illustrating a relation between the temperature TB and the frequency (cumulative times).

### DETAILED DESCRIPTION OF EMBODIMENTS

Hereinafter, an embodiment of the present disclosure will be described in detail with reference to the drawings. In the drawings, the same or corresponding parts are denoted by the same reference numerals, and the description thereof will not be repeated.

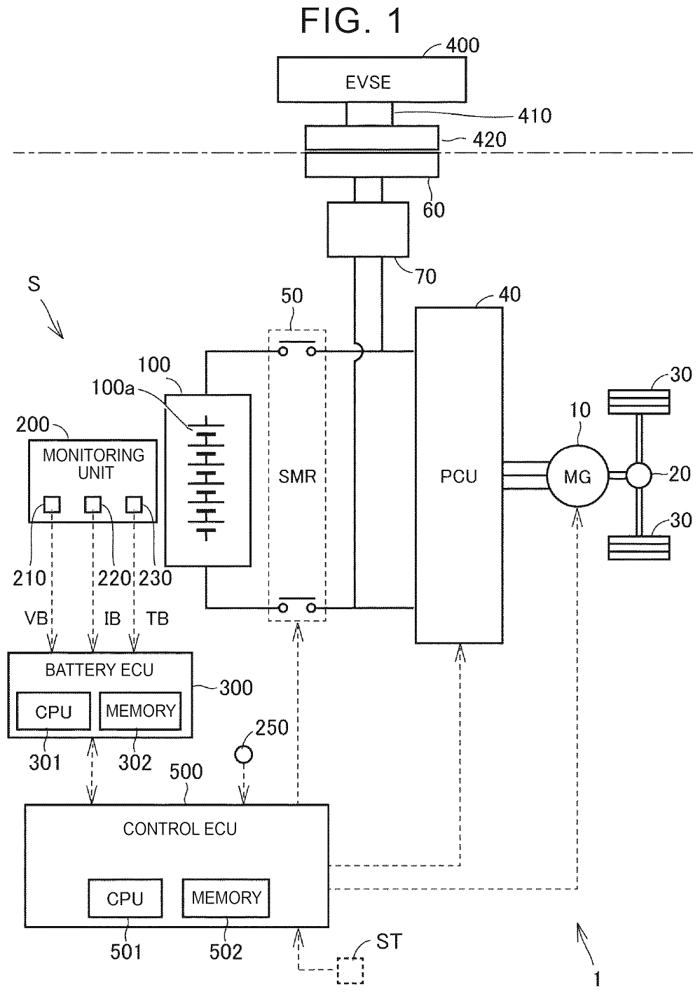

FIG. 1 is an entire configuration diagram of an electrified vehicle 1 in which a battery system S according to the present embodiment is mounted. In the present embodiment, electrified vehicle 1 is, for example, a battery electric vehicle. Electrified vehicle 1 may be a plug-in hybrid electric vehicle equipped with an internal combustion engine and a battery. Electrified vehicle 1 includes a motor generator (MG: Motor Generator) 10 which is a rotary electric machine, power transmission gears 20, drive wheels 30, a power control unit (PCU: Power Control Unit) 40, a system main relay (SMR: System Main Relay) 50, a battery 100, a monitoring unit 200, a battery ECU (Electronic Control Unit) 300 which is an exemplary control device, and a control ECU 500.

MG 10 is, for example, an embedded-structure permanent-magnet synchronous motor (IPM motor), and has a function as an electric motor and a function as a generator. The output-torque of MG 10 is transmitted to the drive wheels 30 via the power transmission gears 20 including a speed reducer, a differential, and the like.

When electrified vehicle 1 is braked, MG 10 is driven by the drive wheels 30, and MG 10 operates as a generator. As a result, MG 10 also functions as a braking device that performs regenerative braking for converting kinetic energy of electrified vehicle 1 into electric power. Regenerated electric power generated by regenerative braking force in the MG 10 is stored in the battery 100.

The PCU 40 is a power conversion device that bidirectionally converts electric power between the MG 10 and the battery 100. PCU 40 includes, for example, inverters and converters that operate based on control signals from the control ECU 500.

The SMR 50 is electrically connected to power lines connecting the battery 100 and the PCU 40. If SMR 50 is ON in response to a control signal from the control ECU 500, power may be exchanged between the battery 100 and PCU 40. On the other hand, 30 when SMR 50 is OFF in response to a control signal from the control ECU 500, the battery 100 is disconnected from PCU 40.

The battery 100 stores electric power for driving MG 10. The battery 100 is a rechargeable DC power source (secondary battery), and is an assembled battery in which a plurality of unit cells (battery cells) 100a are electrically connected in series. The battery 100 corresponds to a “battery” of the present disclosure. The unit cells 100a may be composed of, for example, lithium-ion cells.

The monitoring unit 200 includes a voltage sensor 210, a current sensor 220, and a temperature sensor 230. The voltage sensor 210 detects a voltage VB of the battery 100. The current sensor 220 detects a current IB that is input to or output from the battery 100. When the battery 100 is discharged, the current IB becomes a negative (−) value, and when the battery 100 is charged, the current IB becomes a positive (+) value. The temperature sensor 230 detects a temperature TB of the battery 100. The temperature TB corresponds to an exemplary “battery temperature” of the present disclosure. The sensor outputs the detected signal to the battery ECU 300.

Electrified vehicle 1 includes an inlet 60, and the battery 100 can be externally charged using a charging facility (EVSE: Electric Vehicle Supply Equipment) 400. The inlet 60 is configured to be connectable to a connector 420 provided at a distal end of EVSE 400 charge cable 410. The inlet 60 is electrically connected to a power line connected to the battery 100 via the charging circuit 70. In the present embodiment, when SMR 50 is closed, the inlet 60 and the battery 100 are connected to each other to enable external charging. The charging circuit 70 may include a charging relay. In addition, an inlet 60 (charging circuitry 70) may be connected to a power line between the battery 100 and SMR 50 via a charging relay, and the charging relay may be closed, so that the battery 100 can be externally charged.

The battery ECU 300 includes CPU (Central Processing Unit) 301 and memories 302. The memory 302 includes a RAM (e.g., SRAM (Static Random Access Memory)) and nonvolatile memory (e.g., EEROM (Electrically Erasable Programmable Read-Only Memory)). When energization of RAM is stopped (when the power supply of the battery ECU 300 is lost), RAM loses stored data. In the nonvolatile memory, even if energization of the battery ECU 300 is lost, the stored data does not disappear. The battery

ECU 300 estimates SOC of the battery 100 using the signal received from the monitoring unit 200, and outputs the estimated signal to the control ECU 500. Further, the battery ECU 300 estimates the degree of degradation of the battery 100 and outputs it to the control ECU 500. The battery ECU 300 and the control ECU 500 may be connected by, for example, a CAN (Controller Area Network). In the present embodiment, the battery system S includes a battery 100, a monitoring unit 200, a battery ECU 300, a control ECU 500, and the like.

The control ECU 500 includes a CPU 501 and memories 502. Memory 502, like memory 302, includes RAM and nonvolatile memory. The control ECU 500 controls the devices so that electrified vehicle 1 is in a desired condition based on signals received from the battery ECU 300, signals from various sensors (not shown) (e.g., accelerator operation amount signal, vehicle speed signal, and the like), maps and programs stored in the memory 502, and the like.

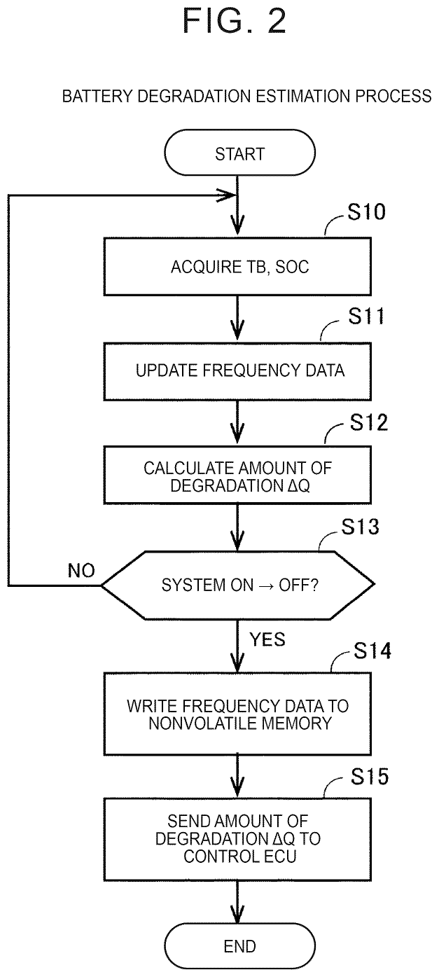

FIG. 2 is a flow chart illustrating an exemplary battery degradation estimation process performed in the battery ECU 300. This flow chart is executed when the power switch (ignition switch) 250 is turned ON and the battery system S is turned ON. When the power switch 250 is turned ON and the battery system S is turned ON, the temperature TB and SOC of the battery 100 are acquired in step (hereinafter, step is abbreviated as “S”) 10. The temperature TB may be detected by the temperature sensor 230. SOC may be calculated and obtained from SOC-OCV (Open Circuit Voltage) property of the battery 100 using the voltage VB detected by the voltage sensor 210.

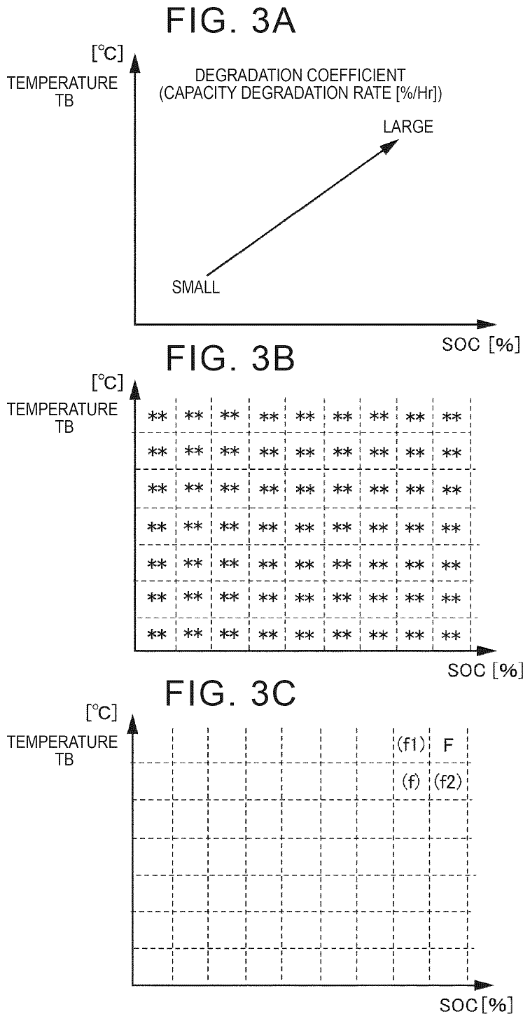

S11 updates the frequency data based on the temperature TB and SOC acquired by S10. FIGS. 3A, 3B, and 3C are diagrams describing a degradation coefficient and frequency data in the present embodiment. FIG. 3A is a diagram describing a degradation coefficient to be described later, and FIG. 3B is a diagram that describing frequency data updated in S11. In FIG. 3B, the vertical axis represents the temperature TB [° C.] and the horizontal axis represents SOC [%]. In the present embodiment, the frequency data is the cumulative time of the time in which the battery 100 exists in the respective regions in the two-dimensional map using the temperature TB and SOC as parameters. For example, the temperature TB may range from −40° C. to +60° C., and SOC may range from 1% to 100%. Also, in the respective regions, the spacing between the temperature TB may be 1° C., or 2° C., or 5° C., and the spacing between SOC may be 1%, or 2%, or 5%. The cumulative time may be, for example, in units of one minute. In S11, the times of the regions corresponding to the temperature TB and SOC acquired by S10 are integrated (accumulated), and the frequency data is updated. The frequency data is stored in SRAM of the memory 302 and updated as needed by S11 being processed.

In the following S12, the degradation rate ΔQ of the battery 100 is calculated. The amount of degradation ΔQ is an amount of degradation (amount of capacity degradation) of the capacity [Ah] of the battery 100, and is an example of “degree of degradation” of the present disclosure. The amount of degradation ΔQ is calculated based on the frequency data updated in S11 and the degradation coefficient. FIG. 3A is a diagram describing the degradation coefficient, where the vertical axis represents the temperature TB and the horizontal axis represents SOC. In the present embodiment, the degradation coefficient is the capacitance degradation rate [%/Hr]. Since the degradation of the battery 100 is accelerated as the temperature TB is higher and SOC is higher (larger), the degradation coefficient is set so that the higher the temperature TB and the higher SOC, the higher the capacity degradation rate. In S12, the amount of capacity degradation of each region is obtained by multiplying the frequency data (cumulative time) and the degradation coefficient (capacity degradation rate) in each region, and the sum of the amount of capacity degradation is calculated as the amount of degradation ΔQ. Note that the capacity degradation of the battery 100 (battery) is known to follow a route law (capacity degradation is proportional to the ½ power of time and cycle number), and the degradation capacity of each region may be obtained from the frequency data (cumulative time) and the degradation coefficient by using the route law.

In S13, it is determined whether or not the battery system S is turned OFF from ON. When the power switch 250 is operated from ON to OFF, it is determined that the battery system S is turned from ON to OFF, and the process proceeds to S14. When the power switch 250 is not operated, a negative determination is made and the process returns to S10, and S13 process is repeatedly executed from S10, S10 to S13 process may be performed at predetermined intervals.

In S14, the frequency data updated by S11 is written to the nonvolatile memory of the memory 302, and then S15 proceeds. The frequency data stored in the nonvolatile memory of the memory 302 is used to restore the frequency data when the frequency data is lost or the like. The time when the frequency data is lost may be, for example, when the power line is removed from the output terminal of the auxiliary battery, which is the power source of the battery ECU 300, and the frequency data stored in SRAM of the memory 302 is lost during the maintenance of electrified vehicle 1.

In S15, after the degradation quantity ΔQ calculated by S12 is transmitted to the control ECU 500, the present routine is ended. The control ECU 500 writes (stores) the received degradation quantity ΔQ into the nonvolatile memory of the memory 502.

In the battery system S, the battery 100 may be replaced. The frequency data stored in the memory 302 (SRAM, nonvolatile memory) of the battery ECU 300 is the frequency data of the battery 100 before replacement. Therefore, when the battery 100 is replaced, the amount of degradation ΔQ of a replaced battery 100 cannot be calculated using the frequency data stored in the memory 302. In the present embodiment, when the battery 100 is replaced, the amount of degradation ΔQ of the replaced battery 100 can be calculated by creating new frequency data.

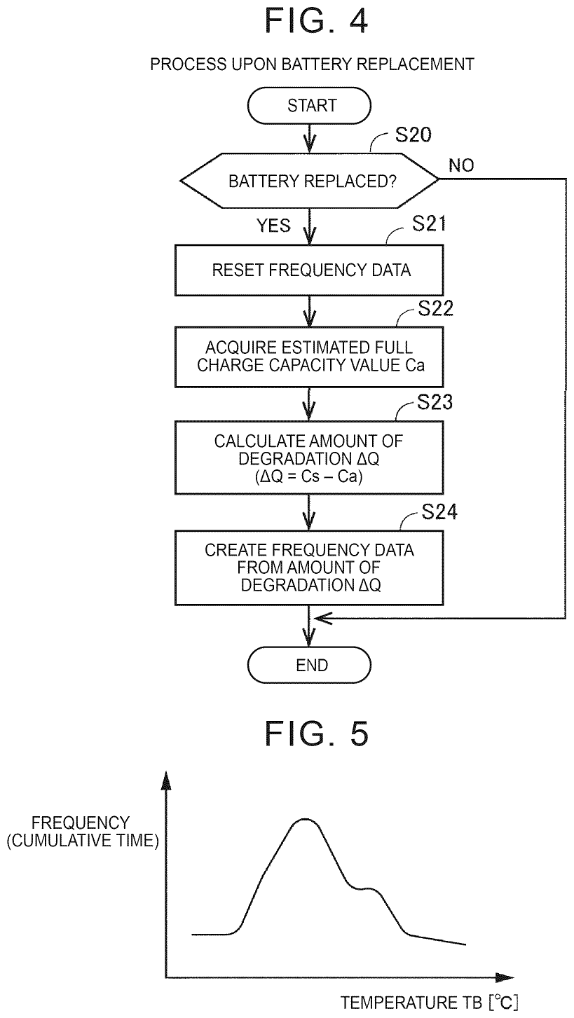

FIG. 4 is a flow chart illustrating an exemplary battery replacement process performed in the battery ECU 300. This flow chart is executed when IG switch (power switch) 250 is turned on and the battery ECU 300 is activated. In S20, it is determined whether or not the batteries have been replaced. For example, the control ECU 500 may determine that a battery replacement has occurred when receiving a replacement signal from a service-tool ST used by a replacement operator of the battery 100. When the identification number (ID) of the battery 100 stored in the memory 302 or the nonvolatile memory of the memory 502 differs from the identification number of the battery 100, it may be determined that the battery has been replaced. Alternatively, when IG switch OFF operating SOC stored in the memory 302 or the nonvolatile memory of the memory 502 differs from ON operating SOC of the IG switch 250 by a predetermined value or more, it may be determined that the batteries have been replaced. When the battery is replaced, the process proceeds to S21, and when the battery is not replaced, the process ends.

In S21, the frequency data stored in the memory 302 is reset. In the present embodiment, SRAM of the memory 302 and the frequency data stored in the nonvolatile memory are reset. The frequency data may be reset, for example, such that the frequency data is NULL. In addition, frequency data may be prepared in advance such that the amount of degradation ΔQ is assumed when the battery 100 at the time of a new battery is used for 10 years, and the frequency data may be used as frequency data after resetting.

In the following S22, the estimated full charge capacity value Ca of the replaced battery 100 is obtained. The estimated full charge capacity value Ca may be obtained in any manner. For example, when the replacement operator of the battery 100 operates the service tool ST to notify the completion of the replacement operation of the battery 100, the battery ECU 300 discharges the battery 100 so that SOC of the replaced battery 100 becomes equal to or less than a predetermined value (for example, 3%). When SCO becomes equal to or less than the predetermined value, the discharging is stopped, and when the period required to eliminate the polarization of the battery 100 has elapsed, the external charging is started using EVSE 400 and the charging current is integrated. External charging may be CCCV (Constant Current Constant Voltage) charging and CC (Constant Current) charging. When the battery 100 is fully charged (when the charging end current or the charging end voltage is reached), the charging is stopped. Then, after leaving for a predetermined period of time, the estimated full charge capacity value Ca of the replaced battery 100 is calculated from SOC at the time of starting charging, SOC at the time of full charging, the charge power amount, and the like obtained from SOC-OCV property. In S22, the estimated full charge capacity value Ca calculated in this way may be obtained.

In S23, the deteriorated quantity ΔQ of the replaced battery 100 is calculated. The memory 302 of the battery ECU 300 stores in advance the full charge capacity Cs of the battery 100 when it is new (manufactured and shipped from the factory). For example, the full charge capacity Cs may be a specified value (designed value) of the battery 100. In S23, the amount of degradation ΔQ is calculated as a difference between the full charge capacity Cs and the estimated full charge capacity value Qa (ΔQ=Cs−Ca). (Note that when the degradation ΔQ is treated as a negative value, the degradation ΔQ may be calculated from ΔQ=Ca−Cs.)

In the following S24, the frequency data is generated based on the amount of degradation ΔQ calculated by S23, and the routine is ended. In the present embodiment, the frequency data is created such that the frequency data in the region having the largest degradation coefficient (capacity degradation rate) becomes the amount of degradation ΔQ. For example, the frequency data F of the region having the highest temperature TB and the largest SOC (the region having the largest degradation coefficient) is calculated as F=ΔQ/S, where S is the degradation coefficient of the region. Then, as shown in FIG. 3C, the frequency data of the region is set to F, the frequency data of the other region is set to NULL, and new frequency data is created. The new frequency data is stored in SRAM of the memory 302. (At this time, the new frequency data may be stored also in the nonvolatile memory of the memory 302.) Thereafter, the new frequency data is updated in S11 of the battery degradation estimation process (FIG. 2).

According to the present embodiment, the battery ECU 300 estimates the amount of degradation ΔQ by using the temperature TB, the frequency data of SOC, and the degradation coefficient set such that the higher the temperature TB, the higher the degradation rate (capacitance degradation rate). When the battery 100 is replaced, the battery ECU 300 obtains the estimated full charge capacity value Ca of the replaced battery 100. Then, the battery ECU 300 calculates the amount of degradation ΔQ of the replaced battery 100 based on the full charge capacity Cs and the estimated full charge capacity value Ca when the battery 100 is new. Then, the battery ECU 300 creates new frequency data so that the frequency data becomes the amount of degradation ΔQ of the replaced battery 100. Then, the battery ECU 300 estimates the amount of degradation ΔQ (degree of degradation) using the new frequency data and the degradation coefficient. Since the new frequency data is created as data corresponding to the amount of degradation ΔQ of the replaced battery 100, the amount of degradation ΔQ of the replaced battery 100 can be estimated using the new frequency data and the degradation coefficient.

FIG. 5 is a diagram illustrating a relation between the temperature TB and the frequency (cumulative times). In FIG. 5, the vertical axis represents frequency (cumulative time), and the horizontal axis represents temperature TB. As shown in FIG. 5, the battery 100 is generally used at a lower temperature side than the normal use temperature region and at a lower frequency than the normal use temperature region.

In the present embodiment, the new frequency data is created such that the frequency data in the region where the temperature TB is high and the degradation coefficient is the largest (the region where the capacitance degradation rate is the largest) becomes the amount of degradation ΔQ. When the degradation coefficient of the region is S, the frequency data F of the region becomes F=ΔQ/S, and the frequency data of the other region is set to NULL. As the degradation coefficient is larger, the frequency data F becomes a smaller value, and therefore, the amount of data is smaller than that of creating the frequency data from the amount of degradation ΔQ in a region having a smaller degradation coefficient (a region having a lower capacity degradation rate). Further, after that (after replacing the battery 100), the temperature TB becomes high and the frequency of being present in the area having the largest degradation coefficient is also small. Accordingly, the frequency data is less likely to overflow after the replacement of the battery 100.

In the above-described embodiment, in S24 (FIG. 4), the frequency data F of the region having the highest temperature TB and the largest SOC (the region having the largest degradation coefficient) is calculated based on the amount of degradation ΔQ, and new frequency data is created. However, the frequency data generated based on the amount of degradation ΔQ may not be a region in which the temperature TB is the highest and SOC is the largest (a region in which the degradation coefficient is the largest). For example, in a region where the temperature TB is the second highest temperature and SOC is the second highest, the frequency data f calculated based on the amount of degradation ΔQ is calculated. As shown in FIG. 3C, the frequency data of the region may be set to f, and the frequency data of the other region may be set to null.

In addition, the frequency data f1, f2 are calculated so that a value obtained by adding the amount of degradation calculated from the frequency data f1 of the region having the highest temperature TB and the second largest SOC and the amount of degradation calculated from the frequency data f2 of the region having the second highest temperature TB and the largest SOC is the amount of degradation ΔQ. As shown in FIG. 3C, the frequency data of the region may be set to f1, f2, and the frequency data of the other region may be set to null. In the present disclosure, the “region where the degradation rate is equal to or higher than a predetermined value” may be, for example, any region of the upper 10% region where the capacity degradation rate is high (the degradation coefficient is large).

In the above-described embodiment, the frequency data is the cumulative time of the time in which the battery 100 exists in the respective regions in the two-dimensional map using the temperature TB and SOC as parameters. However, the frequency data may be cumulative times parameterized solely by the temperature TB. In addition, the frequency data may not be the cumulative time as long as it is a history corresponding to the time in which the battery 100 exists in the area.

When the route rule is used in determining the degree of degradation (amount of degradation ΔQ) of the battery 100, the capacity degradation rate becomes slower as the use time of the battery 100 elapses and the degree of degradation increases. According to the present embodiment, the amount of degradation ΔQ of the replaced battery 100 is calculated, and new frequency data is created from the amount of degradation ΔQ. Therefore, since the new frequency data is created as data in which the use time of the battery 100 (the use time from the new time to the present time) is taken into account, it is possible to accurately estimate the degree of degradation (amount of degradation ΔQ) even after the replacement of the battery ECU 300.

The embodiment disclosed herein shall be construed as exemplary and not restrictive in all respects. The scope of the present disclosure is defined not by the above description of the embodiments but by the claims, and is intended to include all possible modifications within a scope equivalent in meaning and scope to the claims.

What is claimed is:

1. A battery system, comprising:
a battery;
a temperature sensor configured to detect a battery temperature that is a temperature of the battery; and
a control device configured to estimate a degree of degradation of the battery, wherein
the control device is configured to estimate the degree of degradation using frequency data of the battery temperature and a degradation coefficient, and the frequency data is stored in a memory of the control device, the degradation coefficient being set in such a way that a degradation rate increases as the battery temperature increases, and
the control device is configured to, when the battery is replaced,
acquire an estimated full charge capacity value of a replaced battery,
calculate the degree of degradation of the replaced battery based on a full charge capacity when the replaced battery is new and the estimated full charge capacity value,
create new frequency data in such a way that the frequency data becomes the degree of degradation of the replaced battery, and
estimate the degree of degradation using the new frequency data and the degradation coefficient.

2. The battery system according to claim 1, wherein the control device is configured to
create the new frequency data in such a way that the frequency data in a region where the degradation rate is equal to or higher than a predetermined value becomes the degree of degradation of the replaced battery.

3. The battery system according to claim 1, wherein the frequency data is a history of the battery temperature and a state of charge of the battery.

4. The battery system according to claim 3, wherein the control device is configured to store the frequency data in a nonvolatile memory of the control device when the battery system is shut down.

5. An electrified vehicle comprising the battery system according to claim 4.
